(19) United States
(12) Patent Application Publication
(10) Pub. No.: US 2026/0067619 A1
(43) Pub. Date: Mar. 5, 2026

(54) METHOD FOR OPERATING A SPEAKER

(71) Applicant: paragon GmbH & Co. KGaA, Delbrück (DE)

(72) Inventors: Johannes BOEHM, Göttingen (DE); Dirk OLSZEWSKI, Paderborn (DE)

(21) Appl. No.: 19/313,362

(22) Filed: Aug. 28, 2025

(30) Foreign Application Priority Data
Sep. 2, 2024 (LU) 508164

(51) Int. Cl. H04R 3/04; H03F 3/183

(52) U.S. Cl. CPC H04R 3/04; H03F 3/183; H03F 2200/03; H04R 2499/13

(57) ABSTRACT

A method for operating a speaker, in particular a dynamic-speaker, in which a useful signal for producing sound by the speaker is linearized. According to the disclosure, the useful signal is filtered depending on frequency and only a filtered portion of the useful signal is linearized. Advantageously, the useful signal is filtered by a high-pass filter and/or a low-pass filter. In one embodiment, only a portion of the useful signal that is output by the low-pass filter is linearized.

### CROSS-REFERENCE TO RELATED APPLICATION(S)

This application claims the benefit of LU Application No. 508164, filed Sep. 2, 2024, which is incorporated herein by reference in its entirety.

### TECHNICAL FIELD

This disclosure relates generally to a method for operating a speaker, in particular a dynamic speaker, in which a useful signal for generating sound by the speaker is linearized.

### BACKGROUND

It is known from prior art for drive parameters for dynamic speakers to be linearized by digital signal processing in order to improve the sound. Linearization is complex and computationally intensive since various parameters of the speaker are used to perform the necessary calculations.

### SUMMARY

The object of the invention is to reduce the computing effort required for digital signal processing.

According to the invention, this object is attained by filtering the useful signal depending on frequency and linearizing only a filtered portion of the useful signal.

In order to operate the aforementioned mathematical model and perform linearization, various parameters of the speaker must be taken into account, e.g., electrical voice-coil resistance RE, oscillating mass m, mechanical friction, suspension stiffness KME, voice-coil inductance Le, and electromagnetic force factor BI.

Nonlinearities of each parameter are considered in higher-order polynomials, e.g., according to the following formula with a 4^{th}-order polynomial:

$$BL ( x ) = {BI}_{0} + {BI}_{1} \cdot x + B {1}_{2} \cdot {x}^{2} + B {1}_{3} \cdot {x}^{3} + {BI}_{4} \cdot {x}^{4}$$

If each of the above parameters is considered with 4^{th} order, this results in a 24^{th}-order calculation problem in the example at hand. The calculation effort depends on the number of parameters to be tracked and a required sampling rate for determining the parameters. Owing to the invention, the calculation effort can be significantly reduced since linearization only needs to be performed for a portion of the useful signal.

In one embodiment of the invention, the useful signal is filtered by a high-pass filter and/or a low-pass filter, preferably a Linwitz-Riley filter in each case.

In a particularly preferred embodiment of the invention, only a portion of the useful signal that is output by the low-pass filter is linearized. In particular, a portion of the useful signal that is output by the high-pass filter is not linearized.

It has surprisingly been found that a high-frequency portion of the useful signal does not necessarily have to be linearized. This can be explained by the fact that no large diaphragm deflections are required for its reproduction, and linearization is therefore not absolutely necessary. Since low sampling rates are sufficient for the low-frequency portion, the computing effort is additionally reduced.

Advantageously, the low-pass filter has a cutoff frequency in a range of 100 Hz to 1200 Hz, preferably 250 Hz to 1100 Hz, particularly preferably 500 Hz to 1000 Hz.

In a another embodiment of the invention, the portion of the useful signal that is output by the high-pass filter is output with a delay for superposition with the portion of the useful signal that is output by the low-pass filter. Advantageously, the portion of the useful signal that is output by the high-pass filter is output with such a delay that a delay resulting from processing of the portion of the useful signal output by the low-pass filter is compensated. Preferably, the portion of the useful signal that is output by the high-pass filter is output with a delay by a preferably digital delay element.

In one embodiment of the invention, a sampling rate F1 of the portion of the useful signal that is output by the low-pass filter is reduced, preferably to a sampling rate F2, by a data rate converter.

Advantageously, the sampling rate of the portion of the useful signal that is output by the low-pass filter is reduced by the data rate converter before the portion of the useful signal is linearized. Preferably, a sampling rate of the linearized portion of the useful signal is increased to sampling rate F1 by a data rate converter.

In a preferred embodiment of the invention, the portion of the useful signal that is output by the high-pass filter and optionally processed further by the delay and the portion of the useful signal that is output by the low-pass filter and optionally processed further are superposed to form a digital output signal.

Advantageously, the digital output signal is processed by an amplifier comprising a digital-to-analog converter.

In one embodiment of the invention, a measured variable that can be used for linearization, in particular a current and/or a voltage which is used to operate the speaker and/or which is generated by an analog signal output by the amplifier, is measured by a sensor. Alternatively, it would be conceivable to determine a deflection of a diaphragm of the speaker or a sound pressure generated by the speaker.

Advantageously, a measurement signal of the sensor is delayed by a delay in order to be used in the linearization, and/or a sampling rate of the analog signal is reduced to sampling rate F2 by a data rate converter.

Furthermore, the invention relates to a computer program comprising commands which, when the program is executed by a computer, cause the computer to execute the method described above.

Advantageously, the computer program is a computer program stored on a digital signal processor, a microcontroller, a data storage medium, preferably RAM, ROM, CD or the like, or a device, in particular a personal computer, a device with an embedded processor, preferably a digital signal processor or a microcontroller, a computer embedded in a device, or a smartphone, or a signal sequence representing data that is suitable for transmission via a computer network, in particular the internet.

The device may be an amplifier or a speaker, or the device may comprise an amplifier or a speaker.

Furthermore, the invention relates to a data carrier signal that transmits the said computer program.

Furthermore, the invention relates to a processor, in particular a digital signal processor or a microcontroller, on which the computer program is stored, an audio amplifier comprising a digital signal processor or a microcontroller on which the computer program is stored, and/or a sound system comprising an audio amplifier, the audio amplifier comprising a digital signal processor or a microcontroller on which the computer program is stored, and a speaker connected to the audio amplifier.

In an embodiment of the invention, the invention relates to a motor vehicle, in particular an automobile, which is provided with a sound system.

### BRIEF DESCRIPTION OF DRAWINGS

The invention is explained in more detail below with reference to an embodiment and the accompanying drawings, which relate to the embodiment.

FIG. 1 schematically shows steps of the method according to the invention.

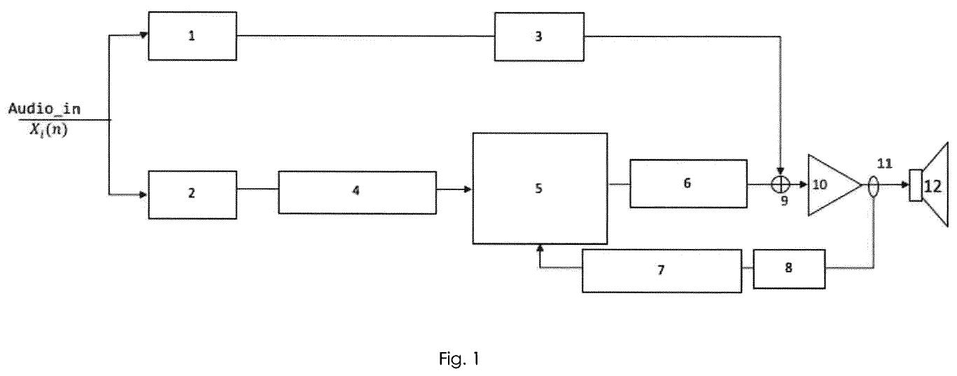

### DETAILED DESCRIPTION

A useful signal Audio_in xᵢ(n) is filtered by a high-pass filter 1 and a low-pass filter 2, both of which may be formed by Linwitz-Riley filters. The cutoff frequencies of the two filters 1, 2 are 800 Hz, for example.

The portion of the useful signal output by the high-pass filter 1 is output with a delay by a delay element 3 for superposition with the portion of the useful signal output by the low-pass filter 2 in such a manner that a delay resulting from processing of the portion of the useful signal output by the low-pass filter 2 is compensated.

A sampling rate F1 of the portion of the useful signal output by the low-pass filter 2 is reduced to a sampling rate F2 by a data rate converter 4 before the portion of the useful signal is linearized by a linearization unit 5. For example, F1 may equal 48 KHz and F2 may equal 6 kHz. A sampling rate of the linearized portion of the useful signal is increased to original sampling rate F1 by a data rate converter 6.

The portion of the useful signal output by the high-pass filter 1 after being delayed by the delay element 3 and the portion of the linearized and delayed useful signal output by the low-pass filter 2 are superposed in a mixer 9 to form a digital output signal. The digital output signal is processed by an amplifier 10 comprising a digital-to-analog converter.

For linearization, current with which a speaker 12 is operated is measured by a current measuring sensor 11. A measurement signal of the current measurement sensor 11 is delayed by another delay element 8 for use in the linearization by the linearization unit 5, and/or a sampling rate of the of the analog signal is reduced to sampling rate F2 by a data rate converter 7, allowing the information obtained from the current measurement sensor 11 to be used for linearization.

1. A method for operating a dynamic speaker, in which a useful signal for producing sound by the speaker is linearized, wherein the useful signal is filtered depending on frequency and only a filtered portion of the useful signal is linearized.

2. The method according to claim 1, wherein in the useful signal is filtered by a high-pass filter and/or a low-pass Linwitz-Riley filter.

3. The method according to claim 1, wherein only a portion of the useful signal that is output by the low-pass filter is linearized.

4. The method according to claim 2, wherein the low-pass filter has a cutoff frequency in a range of 100 Hz to 1200 Hz, preferably of 250 Hz to 1100 Hz, particularly preferably of 500 Hz to 1000 Hz.

5. The method according to claim 2, wherein a portion of the useful signal that is output by the high-pass filter is not linearized.

6. The method according to claim 2, wherein the portion of the useful signal that is output by the high-pass filter is output with a delay for superposition with the portion of the useful signal that is output by the low-pass filter.

7. The method according to claim 2, wherein the portion of the useful signal that is output by the high-pass filter is output with such a delay that a delay resulting from processing of the portion of the useful signal output by the low-pass filter is compensated.

8. The method according to claim 2, wherein the portion of the useful signal that is output by the high-pass filter is output with a delay by a digital delay element.

9. The method according to claim 2, wherein a sampling rate F1 of the portion of the useful signal that is output by the low-pass filter is reduced to a sampling rate F2 by a data rate converter.

10. The method according to claim 2, wherein the sampling rate of the portion of the useful signal that is output by the low-pass filter is reduced by the data rate converter before the portion of the useful signal is linearized.

11. The method according to claim 1, wherein a sampling rate of the linearized portion of the useful signal is increased to sampling rate F1 by a data rate converter.

12. The method according to claim 1, wherein the portion of the useful signal that is output by the high-pass filter and optionally processed further by the delay and the portion of the useful signal that is output by the low-pass filter and optionally processed further are superposed to form a digital output signal.

13. The method according to claim 12, wherein the digital output signal is processed by an amplifier comprising a digital-to-analog converter.

14. The method according to claim 13, wherein a current and/or a voltage which is used to operate the speaker and/or which is generated by an analog signal output by the amplifier is measured by a sensor.

15. The method according to claim 14, wherein a measurement signal of the sensor is delayed by a delay in order to be used in the linearization, and/or a sampling rate of the analog signal is reduced to sampling rate F2 by a data rate converter.

16. A computer program comprising commands which, when the program is executed by a computer, cause the computer to execute the method according to claim 1.

17. The computer program according to claim 16, wherein the computer program is a computer program stored on a digital signal processor, a data storage medium of RAM, ROM, CD, or a personal computer, a device with an embedded processor which is a digital signal processor, a computer embedded in a device, or a smart phone, or a signal sequence representing data that is suitable for transmission via a computer network.

18. The computer program according to claim 16, wherein the device is an amplifier or/and a speaker or that the device comprises an amplifier and/or a speaker.

19. A data carrier signal transmitting the computer program according to claim 16.

20. A digital signal processor or a microcontroller, on which the computer program according to claim 16 is stored.

21. An audio amplifier comprising a processor, wherein the processor is a digital signal processor or a microcontroller, on which the computer program according to claim 16 is stored.

22. A sound system comprising an audio amplifier, the audio amplifier comprising a digital signal processor on which the computer program according to claim 16 is stored, and a speaker connected to the audio amplifier.

23. A motor vehicle, wherein the motor vehicle is an automobile, which is provided with a sound system according to claim 22.
